(19) United States
(12) Patent Application Publication
(10) Pub. No.: US 2024/0178351 A1
(43) Pub. Date: May 30, 2024

(54) DISPLAY DEVICE

(71) Applicant: LG Display Co., Ltd., Seoul (KR)

(72) Inventors: JongBeom Lee, Paju-si (KR); JongSung Kim, Seoul (KR); SunHwa Lee, Goyang-si (KR); ByungHyun Lee, Paju-si (KR); Soyi Lee, Paju-si (KR); Seeun Kim, Seoul (KR)

(73) Assignee: LG Display Co., Ltd., Seoul (KR)

(21) Appl. No.: 18/138,203

(22) Filed: Apr. 24, 2023

(30) Foreign Application Priority Data
Nov. 29, 2022 (KR) 10-2022-0162844

(51) Int. Cl. H01L 33/50; G09F 9/302; H01L 25/075; H01L 25/16; H01L 27/12; H01L 33/10; H01L 33/24; H01L 33/38; H01L 33/62

(52) U.S. Cl. CPC H01L 33/505; G09F 9/3026; H01L 25/0753; H01L 25/167; H01L 27/124; H01L 33/10; H01L 33/24; H01L 33/382; H01L 33/62

(57) ABSTRACT

A display device can include a plurality of pixels disposed on a substrate, at least two sub-pixels disposed in a same pixel among of the plurality of pixels, a light emitting element disposed in the same pixel, and a plurality of color conversion members disposed in the at least two sub-pixels. Each of the plurality of color conversion members overlaps with at least a portion of the light emitting element. Also, the light emitting element is shared by the at least two sub-pixels in the same pixel.

### CROSS-REFERENCE TO RELATED APPLICATIONS

This application claims the benefit of and priority to Korean Patent Application No. 10-2022-0162844 filed on Nov. 29, 2022, in the Republic of Korea, the entire contents of which are hereby expressly incorporated by reference into the present application.

### BACKGROUND

### Technical Field

The present disclosure relates to a display device, and more particularly, to a display device using a light emitting diode (LED).

### Discussion of the Related Art

Display devices used in computer monitors, TVs, and mobile phones include organic light emitting displays (OLEDs) that emit light by themselves, and liquid crystal displays (LCDs) that require a separate light source (e.g., a backlight unit).

Display devices are being applied to more and more various fields of application including not only computer monitors and TVs, but also personal mobile devices, and thus, display devices having a reduced volume and weight while having a wide active area are being studied.

In recent years, display devices including light emitting diodes (LEDs), such as micro LEDs, have received attention as the next-generation display devices. Since the LED is formed of an inorganic material rather than an organic material, it has excellent reliability and has a longer lifespan compared to a liquid crystal display or an organic light emitting display. In addition, the LED has a high lighting speed, high luminous efficiency and excellent stability due to high impact resistance and can display a high-luminance image.

However, implementing a display device that uses LEDs often involves individually placing and aligning millions of small LEDs, which can lead to defective sub-pixels, as well as complex and costly manufacturing processes with lower yields. Thus, there exist a need for improving the efficiency of placing and aligning LEDs, reducing the number of misalignments and defective sub-pixels, and improving yields.

### SUMMARY OF THE DISCLOSURE

An aspect of the present disclosure is to provide a display device capable of implementing a plurality of sub-pixels with one light emitting element.

Another aspect of the present disclosure is to provide a display device allowing for a reduction in total number of light emitting elements disposed in the display device without sacrificing resolution or image quality.

Still another aspect of the present disclosure is to provide a display device capable of reducing the number of processes for transferring light emitting elements and manufacturing costs by reducing the total number of light emitting elements disposed in the display device.

Still another aspect of the present disclosure is to provide a display device in which leakage current flowing to adjacent sub-pixels is minimized.

Objects of the present disclosure are not limited to the above-mentioned objects, and other objects, which are not mentioned above, can be clearly understood by those skilled in the art from the following descriptions.

A display device according to an example embodiment of the present disclosure includes a substrate on which a plurality of pixels each including a plurality of sub-pixels are defined; a light emitting element disposed in each of the plurality of pixels; and a plurality of color conversion members disposed on the light emitting element in each of the plurality of sub-pixels, in which one light emitting element is disposed in the plurality of sub-pixels, and the one light emitting element overlaps the plurality of color conversion members. Accordingly, since a plurality of sub-pixels can be implemented with one light emitting element, the total number of light emitting elements can be reduced and manufacturing costs can be reduced.

Other detailed matters of the example embodiments are included in the detailed description and the drawings.

According to the present disclosure, a plurality of sub-pixels can be implemented with only one light emitting element, and thus the number of light emitting elements required for a display device can be reduced.

According to the present disclosure, it is possible to reduce a manufacturing cost and simplify a transfer process of light emitting elements by reducing the number of light emitting elements.

According to the present disclosure, leakage current between a plurality of sub-pixels corresponding to one light emitting element can be minimized, so that color coordinate distortion can be minimized and display quality can be improved.

According to the present disclosure, a plurality of colors can be displayed using one light emitting element, so that a high efficiency display device capable of being driven with low power can be realized.

The effects according to the present disclosure are not limited to the contents exemplified above, and more various effects are included in the present specification.

### BRIEF DESCRIPTION OF THE DRAWINGS

The accompanying drawings provide a further understanding of the disclosure and can be incorporated in and constitute a part of the disclosure, illustrate embodiments of the disclosure and together with the description serve to explain various principles of the disclosure.

The above and other aspects, features and other advantages of the present disclosure will be more clearly understood from the following detailed description taken in conjunction with the accompanying drawings.

FIG. 1 is a schematic configuration diagram of a display device according to an example embodiment of the present disclosure.

FIG. 2A is a partial cross-sectional view of the display device according to an example embodiment of the present disclosure.

FIG. 2B is a perspective view of a tiling display device according to an example embodiment of the present disclosure.

FIGS. 3 to 5 are enlarged plan views of the display device according to example embodiments of the present disclosure.

FIG. 6 is a cross-sectional view taken along VI-VI′ of FIG. 3.

FIG. 7A to FIG. 8B are views for explaining a method of manufacturing a light emitting element of the display device according to an example embodiment of the present disclosure.

FIG. 9A is a schematic circuit diagram of sub-pixels of a display device according to a comparative example.

FIG. 9B is a diagram for explaining a driving current and a low potential power supply voltage of the sub-pixels of the display device according to the comparative example.

FIG. 10A is a schematic circuit diagram of sub-pixels of the display device according to an example embodiment of the present disclosure.

FIG. 10B is a diagram for explaining a driving current and low potential power supply voltages of the sub-pixels of the display device according to an example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided only so that those skilled in the art can fully understand the disclosures of the present disclosure and the scope of the present disclosure. Therefore, the present disclosure will be defined only by the scope of the appended claims.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies can be omitted to avoid unnecessarily obscuring the subject matter of the present disclosure. The terms such as “including,” “having,” and “comprising” used herein are generally intended to allow other components to be added unless the terms are used with the term “only.” Any references to singular can include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, it can be directly disposed on the another element or layer, or another layer or another element can be interposed therebetween.

Although the terms “first,” “second,” and the like are used for describing various components, these components are not confined by these terms. These terms are merely used for distinguishing one component from the other components. Therefore, a first component to be mentioned below can be a second component in a technical concept of the present disclosure.

Same reference numerals generally denote same elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to example embodiments of the present disclosure will be described in detail with reference to accompanying drawings.

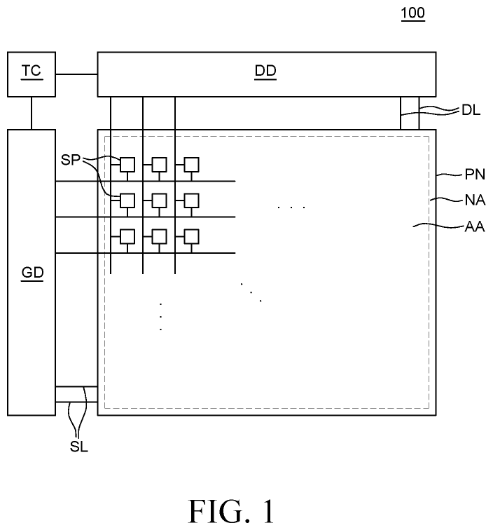

FIG. 1 is a schematic configuration diagram of a display device according to an example embodiment of the present disclosure. In FIG. 1, only a display panel PN, a gate driver GD, a data driver DD, and a timing controller TC among various components of a display device 100 are illustrated for convenience of description.

Referring to FIG. 1, the display device 100 includes the display panel PN including a plurality of sub-pixels SP, the gate driver GD and the data driver DD for supplying various signals to the display panel PN, and the timing controller TC for controlling the gate driver GD and the data driver DD.

The gate driver GD supplies a plurality of scan signals to a plurality of scan lines SL according to a plurality of gate control signals provided from the timing controller TC. Although it is illustrated in FIG. 1 that one gate driver GD is disposed to be spaced apart from one side of the display panel PN, the number and arrangement of gate drivers GD are not limited thereto.

The data driver DD converts image data input from the timing controller TC into a data voltage using a reference gamma voltage according to a plurality of data control signals provided from the timing controller TC. The data driver DD can supply the converted data voltage to a plurality of data lines DL.

The timing controller TC aligns image data input from the outside and supplies it to the data driver DD. The timing controller TC can generate a gate control signal and a data control signal using synchronization signals input from the outside, for example, a dot clock signal, a data enable signal, and a horizontal/vertical synchronization signal. In addition, the timing controller TC can supply the generated gate control signal and data control signal to the gate driver GD and the data driver DD, respectively, to thereby control the gate driver GD and the data driver DD.

The display panel PN, a component for displaying an image to a user, includes the plurality of sub-pixels SP. In the display panel PN, the plurality of scan lines SL and the plurality of data lines DL cross each other, and each of the plurality of sub-pixels SP is connected to the scan line SL and the data line DL. In addition, each of the plurality of sub-pixels SP can be connected to a high potential power supply line, a low potential power supply line, a reference line, and the like.

An active area AA and a non-active area NA surrounding the active area AA can be defined in the display panel PN.

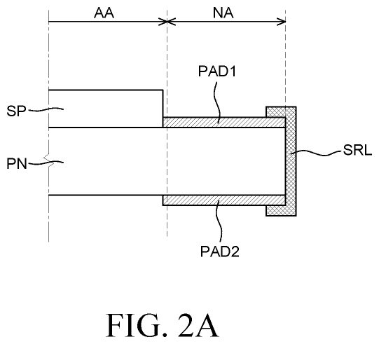

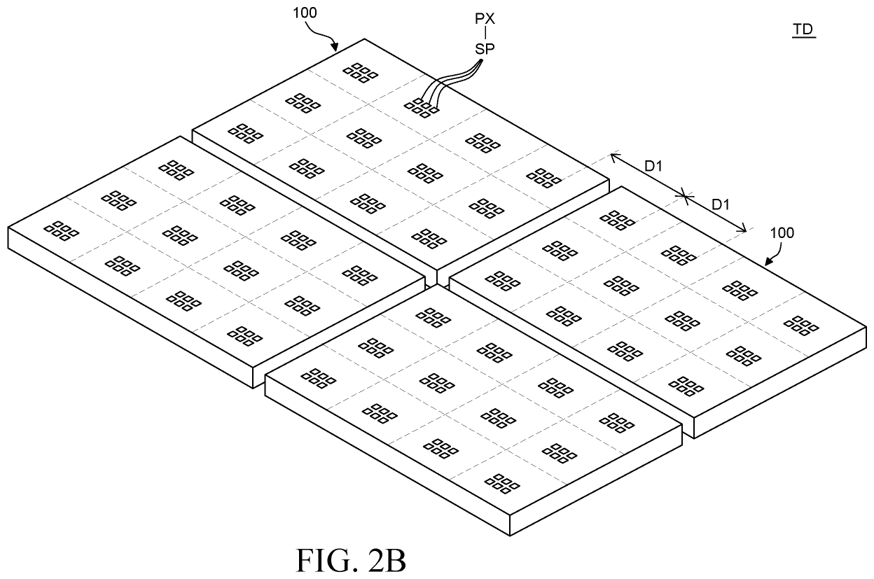

The active area AA is an area where an image is displayed in the display device 100. The plurality of sub-pixels SP constituting a plurality of pixels PX (see FIG. 2B) and a circuit for driving the plurality of sub-pixels SP can be disposed in the active area AA. The plurality of sub-pixels SP are minimum units constituting the active area AA, and n sub-pixels SP can constitute one pixel PX (e.g., a pixel unit of three sub-pixels or four sub-pixels, etc.). A light emitting element can be disposed in each of the plurality of pixels PX. A light emitting element and a thin film transistor for driving the light emitting element can be disposed in the plurality of sub pixels SP.

A plurality of signal lines for transmitting various signals to the plurality of sub-pixels SP are disposed in the active area AA. For example, the plurality of signal lines can include a plurality of data lines DL for supplying data voltages to each of the plurality of sub-pixels SP, a plurality of scan lines SL for supplying gate voltages to each of the plurality of sub-pixels SP, and the like. The plurality of scan lines SL can extend in one direction in the active area AA and be connected to the plurality of sub-pixels SP, and the plurality of data lines DL can extend in a direction different from the one direction in the active area AA and be connected to the plurality of sub-pixels SP. In addition, low potential power supply lines, high potential power supply lines, and the like can be further disposed in the active area AA, but the present disclosure is not limited thereto.

The non-active area NA is an area in which an image is not displayed and can be defined as an area extending from the active area AA. Alternatively, the non-active area NA can be defined as an area adjacent to the active area AA. In the non-active area NA, pad electrodes and link lines for transmitting signals to the sub-pixels SP of the active area AA, and driving ICs such as gate driver ICs and data driver ICs can be disposed.

The non-active area NA can be positioned on a rear surface of the display panel PN, that is, a surface without the sub-pixel SP, or can be omitted, and is not limited to that in the drawings.

Meanwhile, driving units such as the gate driver GD, the data driver DD, and the timing controller TC can be connected to the display panel PN in various manners. For example, the gate driver GD can be mounted in a gate in panel (GIP) method in the non-active area NA, or mounted in a gate in active area (GIA) method between the plurality of sub-pixels SP in the active area AA. For example, the data driver DD and the timing controller TC are formed on a separate flexible film and printed circuit board, and can be electrically connected to the display panel PN in a method of bonding the flexible film and the printed circuit board to pad electrodes formed in the non-active area NA of the display panel PN. If the gate driver GD is mounted in the GIP method, and the data driver DD and the timing controller TC transmit signals to the display panel PN through the pad electrode of the non-active area NA, it is necessary to secure an area of the non-active area NA for disposing the gate driver GD and the pad electrode, and a bezel can increase.

Unlike this, when the gate driver GD is mounted within the active area AA using the GIA method, and the flexible film and the printed circuit board are bonded to the rear surface of the display panel PN by forming side lines SRL (see FIG. 2A) connecting signal lines on a front surface of the display panel PN to the pad electrodes on the rear surface of the display panel PN, the non-active area NA on the front surface of the display panel PN can be maximally reduced. That is, when the gate driver GD, the data driver DD, and the timing controller TC are connected to the display panel PN in the above manner, it is possible to realize a zero-bezel substantially without a bezel. FIGS. 2A and 2B will be referred for a more detailed description. FIG. 2A is a partial cross-sectional view of the display device according to an example embodiment of the present disclosure. FIG. 2B is a perspective view of a tiling display device according to an example embodiment of the present disclosure.

A plurality of the pad electrodes are disposed in the non-active area NA of the display panel PN to transmit various signals to the plurality of sub-pixels SP. For example, in the non-active area NA on the front surface of the display panel PN, a first pad electrode PAD1 for transmitting signals to the plurality of sub-pixels SP is disposed, and a second pad electrode PAD2 electrically connected to driving components such as the flexible film and the printed circuit board is disposed in the non-active area NA on the rear surface of the display panel PN.

In this situation, various signal lines connected to the plurality of sub-pixels SP, for example, scan lines SL or data lines DL, can extend from the active area AA to the non-active area NA and be electrically connected to the first pad electrode PAD1.

The side line SRL is disposed along a side surface of the display panel PN. The side line SRL can electrically connect the first pad electrode PAD1 on the front surface of the display panel PN and the second pad electrode PAD2 on the rear surface of the display panel PN. Accordingly, signals from driving components on the rear surface of the display panel PN can be transferred to the plurality of sub-pixels SP through the second pad electrode PAD2, the side line SRL, and the first pad electrode PAD1. Accordingly, the area of the non-active area NA of the display panel PN can be minimized by forming signal transmission paths from the front surface to the side surface and the rear surface of the display panel PN.

Referring to FIG. 2B, a tiling display device TD having a large screen can be implemented by connecting a plurality of display devices 100. In this situation, when the tiling display device TD is implemented using the display devices 100 with a minimized bezel as illustrated in FIG. 2A, a seam area where an image is not displayed between the display devices 100 is minimized or eliminated, so that display quality can be improved.

For example, the plurality of sub-pixels SP can constitute one pixel PX. A distance DI between an outermost pixel PX of one display device 100 and an outermost pixel PX of another display device 100 adjacent thereto can be implemented to be equal to a distance DI between the pixels PX in one display device 100. Accordingly, the distance of the pixels PX between the display devices 100 is configured to be constant, so that the seam area can be minimized or eliminated.

However, FIGS. 2A and 2B are examples, and the display device 100 according to an example embodiment of the present disclosure can be a general display device having a bezel, but is not limited thereto.

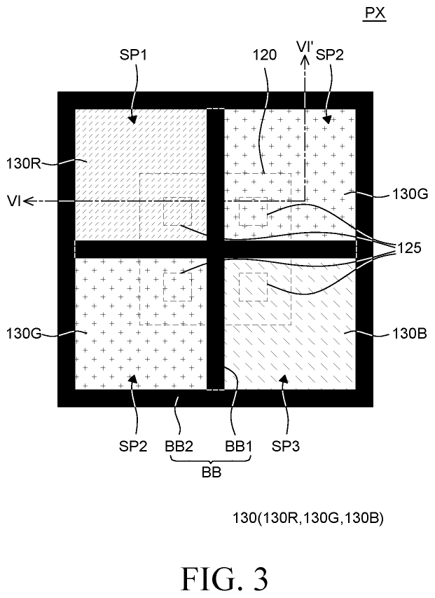

FIGS. 3 to 5 are enlarged plan views of the display device according to example embodiments of the present disclosure. Specifically, FIGS. 3 to 5 are each an enlarged plan view of one pixel (e.g., one pixel unit including multiple sub-pixels) and illustrate only a first bank BB1, a second bank BB2, a light emitting element 120, and a plurality of color conversion members 130, for convenience of description.

First, referring to FIG. 3, the display panel PN includes a plurality of pixels PX each including a plurality of sub-pixels SP. The plurality of sub-pixels SP can include the light emitting element 120 and a circuit to independently emit light.

One pixel PX can include a plurality of sub-pixels SP including a first sub-pixel SP1, a second sub-pixel SP2, and a third sub-pixel SP3. For example, among the plurality of sub-pixels SP, the first sub-pixel SP1 can be a red sub-pixel, the second sub-pixel SP2 can be a green sub-pixel, and the third sub-pixel SP3 can be a blue sub-pixel, but the present disclosure is not limited thereto.

In this situation, the number and arrangement of the plurality of sub-pixels SP constituting one pixel PX or an area of each sub-pixel SP can be variously designed in consideration of luminous efficiency or a viewing angle.

For example, referring to FIG. 3, one pixel PX can include four sub-pixels SP forming a 2×2 matrix array, so that a planar shape thereof can have a quadrangular shape. Also, one first sub-pixel SP1, two second sub-pixels SP2, and one third sub-pixel SP3 can be disposed in one pixel PX.

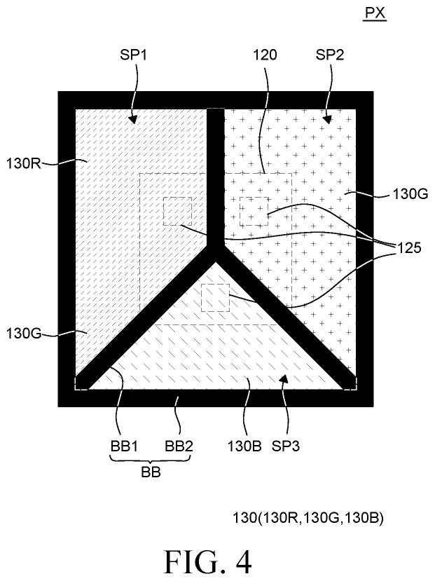

Referring to FIG. 4, one pixel PX has a quadrangular planar shape and can have one first sub-pixel SP1, one second sub-pixel SP2, and one third sub-pixel SP3 disposed therein.

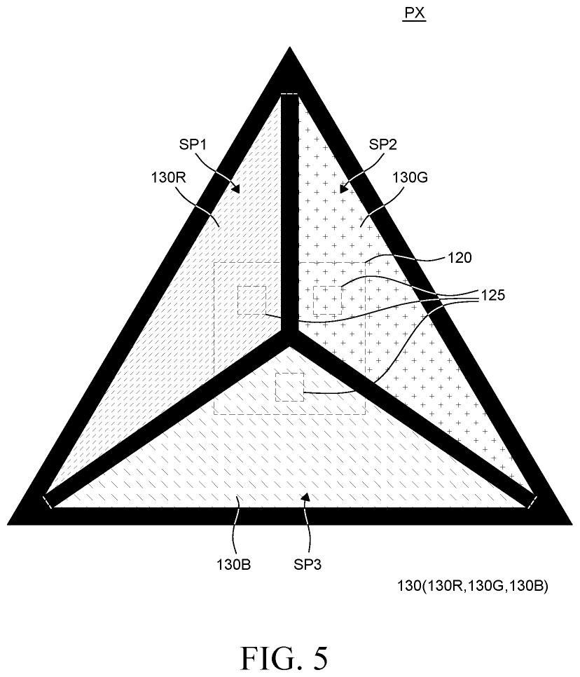

Referring to FIG. 5, one pixel PX has a triangular planar shape and can have one first sub-pixel SP1, one second sub-pixel SP2, and one third sub-pixel SP3 disposed therein.

Also, light emitting elements are usually individually disposed in each of a plurality of sub-pixels to display an image. However, in accordance with an increase in resolution, both the numbers of the plurality of sub-pixels and the plurality of light emitting elements and the number of transfer processes for transferring the plurality of light emitting elements to a display device increases, resulting in an increased manufacturing cost and more chances for light emitting elements to become misaligned or defective. In addition, there is a color deviation of light emitted from each of the plurality of light emitting elements, resulting in a change in color coordinates of the display device. In addition, the plurality of light emitting elements are formed by patterning an epitaxial layer grown from one wafer into a plurality of epitaxial layers. In this etching process, defects can occur in a sidewall of the light emitting element, and luminous efficiency of the light emitting element can decrease.

Accordingly, in the display device 100 according to an example embodiment of the present disclosure, one light emitting element 120 is disposed in the plurality of sub-pixels SP, so that the number of a plurality of the light emitting elements 120 compared to the number of the plurality of sub-pixels SP can be reduced. That is, the plurality of light emitting elements 120 disposed in the plurality of sub-pixels SP can be integrally formed. For example, one light emitting element 120 can be disposed in one pixel PX, and the plurality of sub-pixels SP can be implemented with one light emitting element 120. In other words, a number of sub-pixels in the display device 100 can be greater than a number of light emitting elements 120 in the display device 100. Accordingly, in the display device 100 according to an example embodiment of the present disclosure, a manufacturing cost can be reduced and a transfer process can be simplified. In addition, since the plurality of light emitting elements 120 in the related art are integrally formed with one light emitting element 120, a total area of the sidewall of the light emitting element 120 that is damaged during an etching process of the epitaxial layer can be reduced.

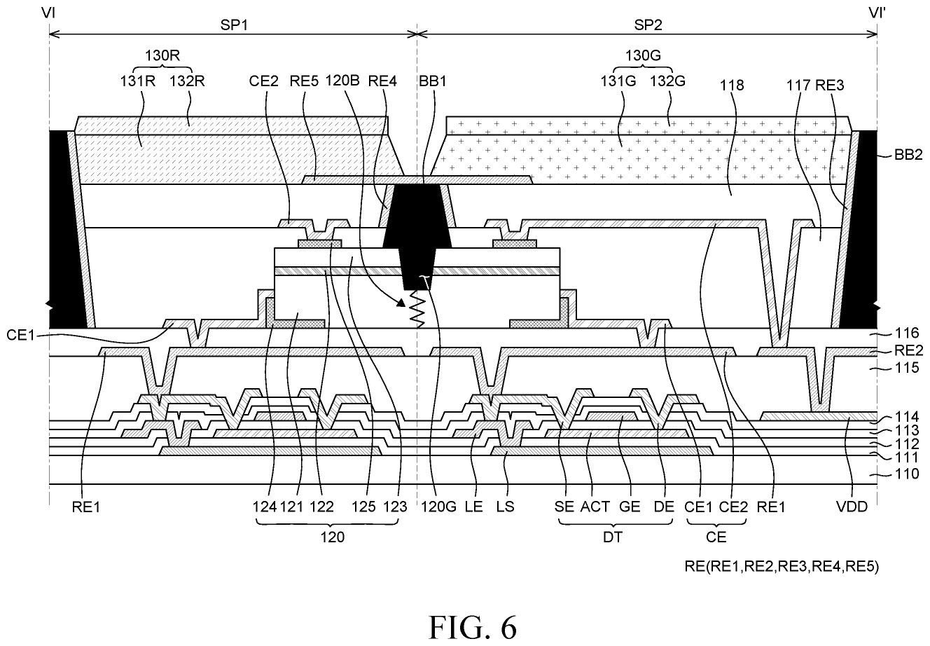

Hereinafter, the light emitting element 120 of the display device 100 according to an example embodiment of the present disclosure will be described in more detail with reference to FIG. 6.

FIG. 6 is a cross-sectional view taken along VI-VI′ of FIG. 3. Specifically, FIG. 6 is a cross-sectional view of a first sub-pixel and a second sub-pixel adjacent to each other.

Referring to FIG. 6, a substrate 110, a buffer layer 111, a gate insulating layer 112, a first interlayer insulating layer 113, a second interlayer insulating layer 114, a first planarization layer 115, an adhesive layer 116, a second planarization layer 117, a third planarization layer 118, a driving transistor DT, the light emitting elements 120, a plurality of reflective layers RE, a plurality of first connection electrodes CE1, a plurality of second connection electrodes CE2, light shielding layers LS, and auxiliary electrodes LE are disposed in each of the plurality of sub-pixels SP of the display panel PN of the display device 100 according to an example embodiment of the present disclosure.

First, the substrate 110 is a component to support various components included in the display device 100 and can be formed of an insulating material. For example, the substrate 110 can be formed of glass, resin or the like. In addition, the substrate 110 can be formed to include a polymer or plastic, or can be formed of a material having flexibility.

The light shielding layer LS is disposed in each of the plurality of sub-pixels SP on the substrate 110. The light shielding layer LS blocks light incident from a lower portion of the substrate 110 into an active layer ACT of the driving transistor DT, which will be described later. The light which is incident into the active layer ACT of the driving transistor DT is blocked by the light shielding layer LS, thereby minimizing leakage current. For example, the active layer ACT of the driving transistor DT can be protected from both sides by the light shielding layer LS and the gate electrode GE.

The buffer layer 111 is disposed on the substrate 110 and the light shielding layer LS. The buffer layer 111 can reduce penetration of moisture or impurities through the substrate 110. The buffer layer 111 can be composed of, for example, a single layer or multiple layers of silicon oxide (SiOx) or silicon nitride (SiNx), but is not limited thereto. However, the buffer layer 111 can be omitted depending on a type of substrate 110 or a type of transistor, but is not limited thereto.

The driving transistor DT is disposed on the buffer layer 111. The driving transistor DT includes the active layer ACT, a gate electrode GE, a source electrode SE, and a drain electrode DE.

The active layer ACT is disposed on the buffer layer 111. The active layer ACT can be formed of a semiconductor material, such as oxide semiconductor, amorphous silicon, or polysilicon, but is not limited thereto.

The gate insulating layer 112 is disposed on the active layer ACT. The gate insulating layer 112 is an insulating layer for insulating the active layer ACT and the gate electrode GE, and can be composed of a single layer or multiple layers of silicon oxide (SiOx) or silicon nitride (SiNx), but is limited thereto.

The gate electrode GE is disposed on the gate insulating layer 112. The gate electrode GE can be formed of a conductive material, such as copper (Cu), aluminum (Al), molybdenum (Mo), nickel (Ni), titanium (Ti), chromium (Cr), or an alloy thereof, but is not limited thereto.

The first interlayer insulating layer 113 and the second interlayer insulating layer 114 are disposed on the gate electrode GE. Contact holes for connecting each of the source electrode SE and the drain electrode DE to the active layer ACT are formed in the first interlayer insulating layer 113 and the second interlayer insulating layer 114. The first interlayer insulating layer 113 and the second interlayer insulating layer 114 are insulating layers for protecting components under the first interlayer insulating layer 113 and the second interlayer insulating layer 114, and can be composed of a single layer or multiple layers of silicon oxide (SiOx) or silicon nitride (SiNx), but are limited thereto.

The source electrode SE and the drain electrode DE electrically connected to the active layer ACT are disposed on the second interlayer insulating layer 114. The source electrode SE and the drain electrode DE can be formed of a conductive material, such as copper (Cu), aluminum (Al), molybdenum (Mo), nickel (Ni), titanium (Ti), chromium (Cr), or an alloy thereof, but are not limited thereto.

Meanwhile, in the present disclosure, it is described that the first interlayer insulating layer 113 and the second interlayer insulating layer 114, that is, a plurality of insulating layers are disposed between the gate electrode GE, and the source electrode SE and the drain electrode DE. However, only one insulating layer can be disposed between the gate electrode GE, and the source electrode SE and the drain electrode DE, but the present disclosure is not limited thereto.

As illustrated in the drawings, when a plurality of insulating layers, such as the first interlayer insulating layer 113 and the second interlayer insulating layer 114, are disposed between the gate electrode GE, and the source electrode SE and the drain electrode DE, an electrode can be additionally formed between the first interlayer insulating layer 113 and the second interlayer insulating layer 114, and the additionally formed electrode can form a capacitor with other components disposed on a lower portion of the first interlayer insulating layer 113 or an upper portion of the second interlayer insulating layer 114.

The auxiliary electrode LE is disposed on the gate insulating layer 112. The auxiliary electrode LE is an electrode electrically connecting the light shielding layer LS under the buffer layer 111 to one of the source electrode SE and the drain electrode DE on the second interlayer insulating layer 114. For example, since the light shielding layer LS is electrically connected to either the source electrode SE or the drain electrode DE through the auxiliary electrode LE and does not operate as a floating gate, so that a variance in threshold voltage of the driving transistor DT which is generated by the light shielding layer LS that is floated can be minimized. Although the light shielding layer LS is illustrated as being connected to the source electrode SE in the drawings, the light shielding layer LS can be connected to the drain electrode DE, but is not limited thereto.

A high potential power supply line VDD is disposed on the second interlayer insulating layer 114. The high potential power supply line VDD, along with the driving transistor DT, can be electrically connected to the light emitting element 120 to emit the light emitting element 120. The high potential power supply line VDD can be formed of a conductive material, such as copper (Cu), aluminum (Al), molybdenum (Mo), nickel (Ni), titanium (Ti), chromium (Cr) or an alloy thereof, but is not limited thereto. The high potential power supply line VDD, the light emitting element 120, the driving transistor DT and the low potential power supply line VSS can be connected in series in each of the plurality of sub-pixels.

The first planarization layer 115 is disposed on the driving transistor DT and the high potential power supply line VDD. The first planarization layer 115 can planarize an upper portion of the substrate 110 on which the driving transistor DT is disposed. The first planarization layer 115 can be composed of a single layer or multiple layers, and can be formed of, for example, photoresist or an acryl-based organic material, but the present disclosure is not limited thereto.

The plurality of reflective layers RE are disposed on the first planarization layer 115. The plurality of reflective layers RE includes a first reflective layer RE1, a second reflective layer RE2, a third reflective layer RE3, a fourth reflective layer RE4, and a fifth reflective layer RE5. The plurality of reflective layers RE can be formed of a conductive material having excellent reflective properties to reflect light emitted from the light emitting element 120. For example, the plurality of reflective layers RE can be formed of a metallic material having high reflective efficiency, such as aluminum (Al) or silver (Ag), but the present disclosure is not limited thereto.

First, the first reflective layer RE1 and the second reflective layer RE2 that are spaced apart from each other are disposed on the first planarization layer 115. The first reflective layer RE1 and the second reflective layer RE2 can serve as electrodes that electrically connect the light emitting element 120 to the high potential power supply line VDD and the driving transistor DT, and reflectors that reflect light emitted from the light emitting element 120, upwardly of the light emitting element 120 and out of the display device 100.

Specifically, the first reflective layer RE1 can electrically connect the driving transistor DT and the light emitting element 120. The first reflective layer RE1 can be connected to the source electrode SE or the drain electrode DE of the driving transistor DT through a contact hole formed in the first planarization layer 115. Also, the first reflective layer RE1 can be electrically connected to a first electrode 124 and a first semiconductor layer 121 of the light emitting element 120 through the first connection electrode CE1 to be described later.

The second reflective layer RE2 can electrically connect the high potential power supply line VDD and the light emitting element 120. The second reflective layer RE2 can be connected to the high potential power supply line VDD through a contact hole formed in the first planarization layer 115, and can be electrically connected to a second electrode 125 and a second semiconductor layer 123 of the light emitting element 120 through the second connection electrode CE2 to be described later.

The adhesive layer 116 is disposed on the first reflective layer RE1 and the second reflective layer RE2. The adhesive layer 116 can be coated on an entire surface of the substrate 110 to fix the light emitting element 120 disposed on the adhesive layer 116 and hold the light emitting element 120 in place. The adhesive layer 116 can be one selected from among, for example, adhesive polymer, epoxy resist, UV resin, polyimides, acrylates, urethanes, and polydimethylsiloxane (PDMS), but is not limited thereto.

One light emitting element 120 is disposed in one pixel PX on the adhesive layer 116. That is, one light emitting element 120 is disposed in the plurality of sub-pixels SP. In other words, a plurality of sub-pixels SP within the same pixel PX having different colors can share the same light emitting element 120 or portions thereof. The light emitting elements 120 are elements that emit light by current, and can include light emitting elements 120 that emit red light, green light, blue light, and the like, and can implement various colors of light including white light through a combination thereof. For example, the light emitting element 120 can be a light emitting diode (LED) or a micro-light emitting diode (LED).

One light emitting element 120 includes the first semiconductor layer 121 overlapping all of the plurality of sub-pixels in one pixel PX, a plurality of light emitting layers 122 overlapping each of the plurality of sub-pixels, a plurality of second semiconductor layers 123, a plurality of first electrodes 124 overlapping each of the plurality of sub-pixels, and a plurality of second electrodes 125 overlapping each of the plurality of sub-pixels.

The first semiconductor layer 121 is disposed on the adhesive layer 116, and the plurality of second semiconductor layers 123 are disposed on the first semiconductor layer 121. The first semiconductor layer 121 can be continuously disposed throughout the plurality of sub-pixels SP within the same pixel PX, and the plurality of second semiconductor layers 123 can be individually disposed to correspond to each of the plurality of sub-pixels SP within the same pixel PX. That is, the first semiconductor layer 121 disposed to correspond to each of the plurality of sub-pixels SP within the one pixel PX can be connected and integrally formed, and the second semiconductor layers 123 disposed to correspond to each of the plurality of sub-pixels SP within the one pixel PX can be separated from each other and disposed independently.

The first semiconductor layer 121 and the plurality of second semiconductor layers 123 can be layers formed by doping a specific material with n-type impurities and p-type impurities. For example, each of the first semiconductor layer 121 and the plurality of second semiconductor layers 123 can be layers formed by doping materials, such as gallium nitride (GaN), indium aluminum phosphide (InAlP), gallium arsenide (GaAs), and the like, with n-type impurities and p-type impurities. In addition, the p-type impurity can be magnesium (Mg), zinc (Zn), beryllium (Be) or the like, and the n-type impurity can be silicon (Si), germanium (Ge), tin (Sn) or the like, but the present disclosure is not limited thereto.

The plurality of light emitting layers 122 are disposed between the first semiconductor layer 121 and the plurality of second semiconductor layers 123. The plurality of light emitting layers 122 can receive holes and electrons from the first semiconductor layer 121 and the plurality of second semiconductor layers 123 to emit light. The plurality of light emitting layers 122 can be formed to have a single or multi-quantum well (MQW) structure, and can be formed of, for example, indium gallium nitride (InGaN) or gallium nitride (GaN), but the present disclosure is not limited thereto.

In addition, referring to FIGS. 3 and 6 together, the light emitting element 120 can have a groove 120G by partially etching the second semiconductor layer 123 and the light emitting layer 122 and an upper portion of the first semiconductor layer 121 in an area overlapping a boundary between the plurality of sub-pixels SP. The groove 120G can overlap the boundary between the plurality of sub-pixels SP, and can be formed by removing at least the second semiconductor layer 123 and the light emitting layer 122 of the light emitting element 120 among components of the light emitting element 120. By forming the groove 120G in a central portion of the light emitting element 120, the one larger light emitting layer 122 disposed in one light emitting element 120 can be separated into multiple pieces for the plurality of sub-pixels SP. Accordingly, one light emitting element 120 disposed in the plurality of sub-pixels SP can include the plurality of light emitting layers 122, and can drive the plurality of light emitting layers 122, separately, and independently drive the plurality of sub-pixels SP within the same pixel PX.

The plurality of first electrodes 124 are disposed on a side surface and a lower surface of the first semiconductor layer 121. The plurality of first electrodes 124 are electrodes for electrically connecting the driving transistor DT with the first semiconductor layer 121. Each of the plurality of first electrodes 124 can be disposed to correspond to each of the plurality of sub-pixels SP. Since the plurality of first electrodes 124 need to transfer different driving currents to the corresponding light emitting layers 122 of each of the plurality of sub-pixels SP, they can be separately disposed for each of the plurality of sub-pixels SP within the same pixel PX. For example, when one light emitting element 120 is disposed in four sub-pixels SP of the same pixel PX, four first electrodes 124 can be disposed to correspond to each of the four sub-pixels SP.

The plurality of first electrodes 124 can be formed of a conductive material, for example, a transparent conductive material such as indium tin oxide (ITO) or indium zinc oxide (IZO), or can be formed of an opaque conductive material such as titanium (Ti), gold (Au), silver (Ag), copper (Cu) or an alloy thereof, but the present disclosure is not limited thereto.

The plurality of second electrodes 125 are disposed on the second semiconductor layer 123. Each of the plurality of second electrodes 125 can be disposed on an upper surface of each of the plurality of second semiconductor layers 123. The plurality of second electrodes 125 are electrodes for electrically connecting the high potential power supply line VDD with the second semiconductor layer 123. The plurality of second electrodes 125 can be formed of a conductive material, for example, a transparent conductive material such as indium tin oxide (ITO) or indium zinc oxide (IZO), or can be formed of an opaque conductive material such as titanium (Ti), gold (Au), silver (Ag), copper (Cu) or an alloy thereof, but the present disclosure is not limited thereto.

Meanwhile, the light emitting element 120 can further include an encapsulation layer surrounding the first semiconductor layer 121, the plurality of light emitting layers 122, the plurality of second semiconductor layers 123, the plurality of first electrodes 124, and the plurality of second electrodes 125. The encapsulation layer is formed of an insulating material and can protect the first semiconductor layer 121, the light emitting layer 122, and the second semiconductor layer 123. Further, contact holes exposing the plurality of first electrodes 124 and the plurality of second electrodes 125 are formed in the encapsulation layer, so that the first connection electrodes CE1 and the second connection electrodes CE2 to be described later and the plurality of first electrodes 124 and the plurality of second electrodes 125 can be electrically connected.

The plurality of connection electrodes CE are disposed on the adhesive layer 116. The plurality of connection electrodes CE include the plurality of first connection electrodes CE1 and the plurality of second connection electrodes CE2.

First, the first connection electrode CE1 is disposed on a side portion of the light emitting element 120 on the adhesive layer 116. The first connection electrode CE1 is an electrode for electrically connecting the light emitting element 120 with the driving transistor DT. Each of the plurality of first connection electrodes CE1 can be disposed to correspond to one of the plurality of sub-pixels SP within the same pixel PX. Since the plurality of first connection electrodes CE1 need to transfer different driving currents to the corresponding light emitting layers 122 of each of the plurality of sub-pixels SP, they can be disposed separately for each of the plurality of sub-pixels SP.

The plurality of first connection electrodes CE1 can be electrically connected to the first reflective layers RE1 through contact holes formed in the adhesive layer 116. Also, the plurality of first connection electrodes CE1 can be disposed to cover at least a portion of a side surface of the light emitting element 120 and electrically connected to the first semiconductor layer 121 and the plurality of first electrodes 124. Accordingly, the first semiconductor layer 121 and the first electrode 124 can be electrically connected to the driving transistor DT through the first connection electrode CE1 and the first reflective layer RE1. The plurality of first connection electrodes CE1 can be formed of a conductive material, for example, a transparent conductive material such as indium tin oxide (ITO) or indium zinc oxide (IZO), but is not limited thereto.

The second planarization layer 117 is disposed on the light emitting element 120, the plurality of first connection electrodes CE1, and the adhesive layer 116. The second planarization layer 117 can planarize an upper portion of the substrate 110 on which the light emitting element 120 is disposed, and can fix the light emitting element 120 onto the substrate 110, together with the adhesive layer 116 (e.g., the light emitting element 120 can be sandwiched between the adhesive layer 116 and the second planarization layer 117). The second planarization layer 117 can be composed of a single layer or multiple layers, and can be formed of, for example, photoresist or an acryl-based organic material, but is not limited thereto.

The plurality of second connection electrodes CE2 are disposed on the second planarization layer 117. The plurality of second connection electrodes CE2 are electrodes for electrically connecting the second electrodes 125 and the second semiconductor layers 123 of the plurality of light emitting elements 120 and the high potential power supply lines VDD. Each of the plurality of second connection electrodes CE2 can be disposed to correspond to one of the plurality of sub-pixels SP within the same pixel PX. The plurality of second connection electrodes CE2 can electrically connect the plurality of second electrodes 125 corresponding to each of the plurality of sub-pixels SP to the high potential power supply lines VDD. The plurality of second connection electrodes CE2 can be formed of a conductive material, for example, a transparent conductive material such as indium tin oxide (ITO) or indium zinc oxide (IZO), but the present disclosure is not limited thereto.

Meanwhile, although FIG. 6 illustrates that the plurality of second connection electrodes CE2 are respectively connected to the plurality of second electrodes 125, the plurality of second electrodes 125 included in one light emitting element 120 can be connected to one second connection electrode CE2. In this situation, the second connection electrode CE2 can cover both the light emitting element 120 and an upper portion of the first bank BB1 and can be connected to the plurality of second electrodes 125, but is not limited thereto.

The first bank BB1 is disposed on the adhesive layer 116 and the light emitting element 120. The first bank BB1 is disposed between the plurality of sub-pixels SP constituting one pixel PX and can reduce color mixing of light of each of the plurality of sub-pixels SP in the same one pixel PX. The first bank BB1 can be disposed along the boundary of the plurality of sub-pixels SP included in one pixel PX. The first bank BB1 is disposed along the boundary between the plurality of sub-pixels SP and can also be disposed in the groove 120G of the light emitting element 120. The first bank BB1 can be disposed to fill the groove 120G of the light emitting element 120, thereby minimizing a phenomenon in which light emitted from each of the plurality of light emitting layers 122 included in one light emitting element 120 travels to an area of the sub-pixel SP adjacent thereto. The first bank BB1 can be formed of an opaque insulating material, for example, black resin, but is not limited thereto.

The second bank BB2 is disposed on the adhesive layer 116. The second bank BB2 can be disposed between the plurality of pixels PX and can be disposed along a boundary between the pixels PX. The second bank BB2 can minimize color mixing caused as light emitted from one pixel PX travels to another pixel PX adjacent thereto. The second bank BB2 can be formed of an opaque insulating material, for example, black resin, but is not limited thereto. For example, the second bank BB2 can be thicker than the first bank BB1.

In this situation, the second bank BB2 can be connected to the first bank BB1. The second bank BB2 disposed along the boundary of the pixels PX can come into contact with the first bank BB1 disposed along the boundary between the plurality of sub-pixels SP included in one pixel PX. Accordingly, the first bank BB1 and the second bank BB2 can distinguish different areas in which the plurality of sub-pixels SP and the plurality of pixels PX are formed.

The third reflective layer RE3 is disposed on a side surface of the second bank BB2. The third reflective layer RE3 can be disposed on the side surface of the second bank BB2 to reflect light facing the side surface among the light emitted from the light emitting element 120, upwardly of the substrate 110 and out of the display device 100. The third reflective layer RE3 can improve light extraction efficiency by reflecting light emitted from one pixel PX, upwardly of the substrate 110 and out of the display device 100 toward a viewer.

The fourth reflective layer RE4 is disposed on a side surface of the first bank BB1. Similarly to the third reflective layer RE3, the fourth reflective layer RE4 can reflect light facing the side surface of the first bank BB1 among the light emitted from the light emitting element 120, upwardly of the substrate 110. The fourth reflective layer RE4 can improve light extraction efficiency by reflecting light emitted from one sub-pixel SP, upwardly of the substrate 110. The fourth reflective layer RE4 can also reflect light emitted from one sub-pixel SP in a direction away from an adjacent sub-pixel SP, in order better prevent color mixing.

The third planarization layer 118 is disposed on the fourth reflective layer RE4, the first connection electrode CE1, and the second connection electrode CE2. The third planarization layer 118 can planarize an upper portion of the substrate 110. The third planarization layer 118 can be composed of a single layer or multiple layers, and can be formed of, for example, photoresist or an acryl-based organic material, but is not limited thereto.

The fifth reflective layer RE5 is disposed on the third planarization layer 118. The fifth reflective layer RE5 can be disposed to overlap the light emitting element 120. The fifth reflective layer RE5 can have a shape corresponding to a planar shape of the light emitting element 120. The fifth reflective layer RE5 can reflect light that directly faces upwardly of the light emitting element 120 among the light emitted from the light emitting element 120. The fifth reflective layer RE5 reflects light emitted from the light emitting element 120 toward an empty space between the first bank BB1 and the light emitting element 120 so that the light is diffused throughout the sub-pixels SP. For example, the fifth reflective layer RE5 can have an overhang portion or eave portion located above the fourth reflective layer RE4, and together, the fifth reflective layer RE5 and fourth reflective layer RE4 can better reflect light emitted from one sub-pixel SP in a direction away from an adjacent sub-pixel SP, in order better prevent color mixing.

Specifically, it is difficult to pattern a color conversion layer to be described below with a size of a certain level or less. That is, there is a limit to reducing the size of the color conversion layer. In this situation, the light emitting element 120 is a micro-LED having a micro-unit size as described above, and it can be difficult to implement a color conversion layer with a tiny size corresponding to the light emitting element 120, and the color conversion layer can be formed to have a size larger than that of the light emitting element 120. As illustrated in FIGS. 3 to 5, when viewed on a plane, the light emitting element 120 has a size smaller than that of the color conversion layer and can overlap only a portion of the color conversion layer (e.g., a corner of the light emitting element 120 can overlap just a corner of one of the color conversion layers). Thus, the light emitted from the light emitting element 120 is concentrated on only a portion of the color conversion layer (overlapping portion) overlapping the light emitting element 120, and the light is not concentrated on a remaining portion of the color conversion layer (non-overlapping portion) that does not overlap the light emitting element 120, whereby color conversion efficiency can decrease. Accordingly, the fifth reflective layer RE5 is formed directly above the light emitting element 120 so that the light is not concentrated only above the light emitting element 120 and can be evenly directed to an area outside the light emitting element 120 (e.g., to further provide a type of edge lighting technique). The fifth reflective layer RE5 can be configured to reflect light emitted from the light emitting element 120 to the non-overlapping portion of each of the plurality of color conversion members, in order to fully irradiate the corresponding color conversion member with light.

In FIG. 6, the fifth reflective layer RE5 is illustrated as having a size smaller than that of the light emitting element 120, but the fifth reflective layer RE5 can be formed to have a size corresponding to or equal to that of the light emitting element 120, but the present disclosure is not limited thereto.

Referring to FIGS. 3 and 6 together, the plurality of color conversion members 130 are disposed on the third planarization layer 118 and the fifth reflective layer RE5. The plurality of color conversion members 130 can convert the light emitted from the light emitting element 120 into light of various colors. The plurality of color conversion members 130 have a size larger than that of the light emitting element 120, so that the plurality of color conversion members 130 can include a portion overlapping the light emitting element 120 and another portion protruding outwardly of the light emitting element 120 and not overlapping the light emitting element 120. The plurality of color conversion members 130 include a first color conversion member 130R, a second color conversion member 130G, and a third color conversion member 130B. Also, the light emitted from the corresponding portion of the light emitting element 120 can bounce around and be reflected off of and between the different reflective layers in order to fully irradiate light onto the portion of the color conversion member that does not directly overlap with the light emitting element 120.

Hereinafter, for convenience of description, descriptions are made assuming that the light emitting element 120 is a blue light emitting element, and the first color conversion member 130R, the second color conversion member 130G, and the third color conversion member 130B are a red color conversion member, a green color conversion member, and a blue color conversion member, respectively, but the present disclosure is not limited thereto.

The first color conversion member 130R is disposed in the first sub-pixel SP1 and can convert blue light emitted from the light emitting element 120 into red light. The second color conversion member 130G is disposed in the second sub-pixel SP2 and can convert blue light emitted from the light emitting element 120 into green light. The third color conversion member 130B is disposed in the third sub-pixel SP3 and can convert blue light emitted from the light emitting element 120 into blue light with a higher purity and can also transmit the blue light emitted from the light emitting element 120 as it is.

Each of the plurality of color conversion members 130 includes a color conversion layer and a color filter disposed on the color conversion layer. For example, the first color conversion member 130R includes a first color conversion layer 131R and a first color filter 132R, the second color conversion member 130G includes a second color conversion layer 131G and a second color filter 132G, and the third color conversion member 130B includes a third color conversion layer and a third color filter.

The plurality of color conversion layers can include a color conversion material, such as quantum dots, nano phosphors, or organic phosphors. The plurality of color conversion layers can be disposed on the bank in each of the plurality of sub-pixels. The color conversion material included in the plurality of color conversion layers can absorb light emitted from the light emitting element 120 and emit light of a different wavelength. For example, the first color conversion layer 131R can include a color conversion material that absorbs blue light and emits red light, and the second color conversion layer 131G can include a color conversion material that absorbs blue light and emits green light. Since the light emitted from the light emitting element 120 is blue light, the third color conversion layer can be formed of only a transparent material, but can further include a separate color conversion material to improve color purity.

A plurality of color filters are disposed on the plurality of color conversion layers. The plurality of color filters are disposed to correspond to the plurality of sub-pixels SP. The plurality of color filters can improve color purity of light displayed in the sub-pixels SP. The plurality of color filters can transmit only light of a specific wavelength and absorb light of other wavelengths, thereby improving color purity of light emitted from each sub-pixel SP. For example, the green and red color filters can block any remaining blue light emitted from the light emitting element 120 that was not converted by the corresponding color conversion layer.

For example, the first color filter 132R disposed in the first sub-pixel SP1 can absorb a portion of blue light that has not been converted in the color conversion layer and transmit only red light that has been converted in the color conversion layer. The second color filter 132G disposed in the second sub-pixel SP2 can absorb a portion of blue light that has not been converted in the color conversion layer and transmit only green light that has been converted in the color conversion layer. The third color filter disposed in the third sub-pixel SP3 can transmit only blue light.

Therefore, in the display device 100 according to an example embodiment of the present disclosure, only one light emitting element 120 is disposed in the plurality of sub-pixels SP within the same pixel PX, so that manufacturing processes and manufacturing costs can be reduced. In other words, the sub-pixels in the same pixel PX can all share the same light emitting element 120. One light emitting element 120 can be disposed to correspond to one pixel PX including the plurality of sub-pixels SP. In this situation, one light emitting element 120 includes the groove 120G formed along the boundary of the plurality of sub-pixels SP, so that the first semiconductor layer 121 is integrally formed but the light emitting layer 122 and the second semiconductor layer 123 can be separated into a plurality of light emitting layers and a plurality of second semiconductor layers, respectively. That is, the plurality of light emitting layers 122 and the plurality of second semiconductor layers 123 can be separated from each other with the groove 120G therebetween. As the light emitting layer 122 and the second semiconductor layer 123 are separated for each of the plurality of sub-pixels SP, each of the plurality of sub-pixels SP can be independently driven. In addition, by forming the first bank BB1 in the groove 120G of the light emitting element 120, it is possible to prevent light emitted from each light emitting layer 122 from traveling to the sub-pixels SP adjacent thereto and causing color mixing. Accordingly, each of the plurality of sub-pixels SP within the same pixel PX can be driven with only one light emitting element 120 by forming the groove 120G overlapping the boundary of the plurality of sub-pixels SP in one light emitting element 120. Accordingly, the total number of light emitting elements 120 can be reduced, a transfer process of the light emitting elements 120 can be simplified, and manufacturing costs can be reduced and yields can be improved since there are fewer chances of misaligning light emitting elements and given that the same type of light emitting element can be used for all the sub-pixels in the display device.

In this situation, after self-assembling the light emitting elements on a separate assembly substrate, the self-assembled light emitting elements on the assembly substrate can be transferred to the display panel PN. A pair of assembly electrodes forming an electric field can be formed on the assembly substrate at a position corresponding to each of the plurality of pixels PX. In addition, when the assembly substrate and the plurality of light emitting elements are put into a fluid and then, an electric field is formed on the assembly electrodes, the light emitting element 120 can be dielectrically polarized and have a polarity, and the dielectrically polarized light emitting element 120 can be moved or fixed in a specific direction by dielectrophoresis (DEP), that is, an electric field. Accordingly, the plurality of light emitting elements 120 can be temporarily self-assembled on the assembly electrode of the assembly substrate by using dielectrophoresis. Thereafter, the light emitting elements 120 self-assembled to correspond to the plurality of pixels PX can be transferred to the display panel PN at once using a donor. However, the light emitting elements 120 can also be transferred in a method other than a self-assembling method described above, but the present disclosure is not limited thereto.

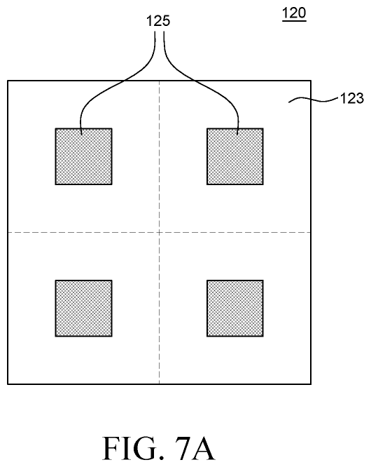

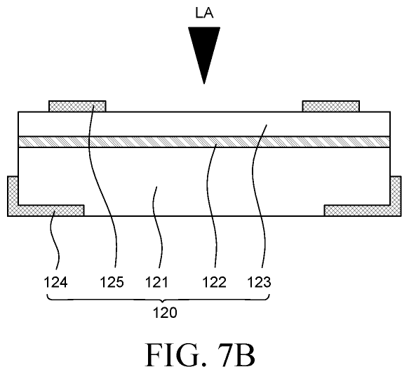

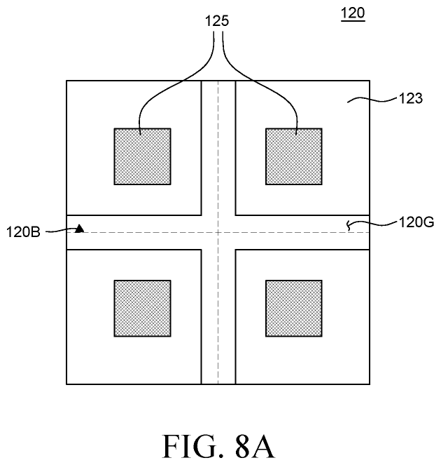

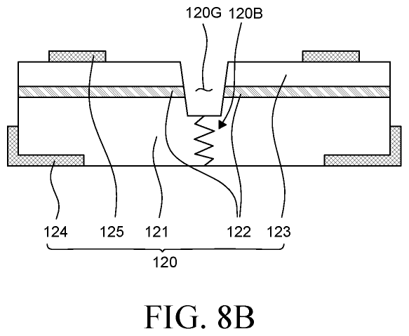

Meanwhile, the first semiconductor layer 121 included in one light emitting element 120 is integrally formed without being separated. That is, the plurality of light emitting layers 122 can be disposed on one first semiconductor layer 121, and the plurality of light emitting layers 122 can share one first semiconductor layer 121. In this situation, when light is emitted from the light emitting layer 122 corresponding to one sub-pixel SP among the plurality of light emitting layers 122, a driving current that is supplied to the light emitting layer 122 can flow to the light emitting layers 122 of adjacent sub-pixels SP through the first semiconductor layer 121. As the plurality of light emitting layers 122 share one first semiconductor layer 121, leakage current may flow to the adjacent sub-pixels SP through the first semiconductor layer 121. Therefore, in the display device 100 according to an example embodiment of the present disclosure, a leakage current blocking unit 120B (see FIG. 8A) can be formed in the light emitting element 120 to minimize a leakage current flow to the adjacent sub-pixels SP. The leakage current blocking unit 120B will be described with reference to FIG. 7A to FIG. 8B.

FIG. 7A to FIG. 8B are views for explaining a method of manufacturing a light emitting element of the display device according to an example embodiment of the present disclosure. FIG. 7A to FIG. 8B are views for explaining a method for reducing leakage current generated from one light emitting element. FIG. 7A and FIG. 7B are a plan view and a cross-sectional view of the light emitting element 120, respectively, before forming the groove 120G and the leakage current blocking unit 120B. FIG. 8A and FIG. 8B are a plan view and a cross-sectional view of the light emitting element 120, respectively, after forming the groove 120G and the leakage current blocking unit 120B.

Referring to FIGS. 7A and 7B, the groove 120G can be formed by irradiating a laser LA onto the light emitting element 120 in which the first semiconductor layer 121, the light emitting layer 122, the second semiconductor layer 123, the first electrodes 124, and the second electrodes 125 are formed. The groove 120G separating the second semiconductor layer 123 and the light emitting layer 122 into a plurality of second semiconductor layers and a plurality of light emitting layers, respectively, can be formed by irradiating the light emitting element 120 with the laser LA.

Although the drawings illustrate that the groove 120G is formed in the light emitting element 120 by irradiating the laser LA, the groove 120G can be formed by a wet etching method using an etchant such as HF instead of the laser LA, but the present disclosure is not limited thereto.

Referring to FIGS. 8A and 8B, the leakage current blocking unit 120B can be formed by irradiating the laser LA again onto the first semiconductor layer 121 overlapping the groove 120G. The first semiconductor layer 121 can be formed of crystal having regularity, for example, is formed of a single crystal of gallium nitride (GaN), and the single crystal of gallium nitride has regularity and high electron mobility. When damage is applied to the first semiconductor layer 121 by irradiating the laser LA thereto, the regularity of gallium nitride is removed so that no more current can flow therethrough. Accordingly, the leakage current blocking unit 120B can be formed by irradiating the first semiconductor layer 121 overlapping the groove 120G with the laser LA, and leaking of a driving current to the adjacent light emitting layer 122 through the first semiconductor layer 121 can be minimized. The leakage current blocking unit 120 can overlap the groove 120G and be integrally formed with the first semiconductor layer 121, and the leakage current blocking unit 120B can be a portion from which the regularity of the first semiconductor layer 121 is removed. For example, the laser LA can be irradiated a second time in groove 120G to damage portions of the first semiconductor layer 121 just enough the alter the crystalline structure in areas between the sub-pixels but without cutting through the first semiconductor layer 121, in order to prevent leakage current from flowing between adjacent sub-pixels.

Since the leakage current blocking unit 120B is formed by removing only the regularity of the first semiconductor layer 121 without physically separating the first semiconductor layer 121, it can be confirmed by analyzing film quality of the first semiconductor layer 121 or measuring a current flow of the first semiconductor layer 121.

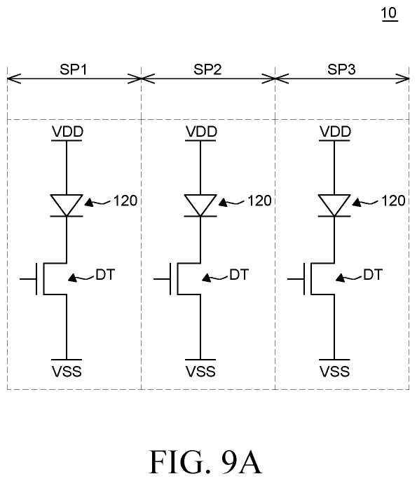

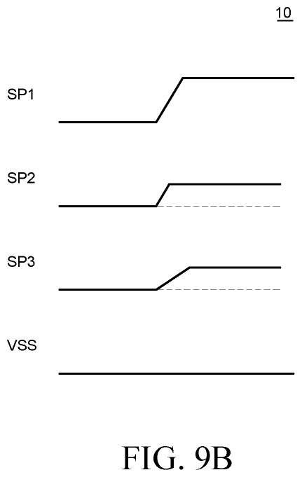

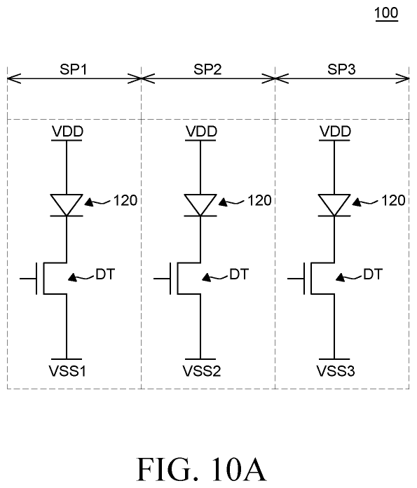

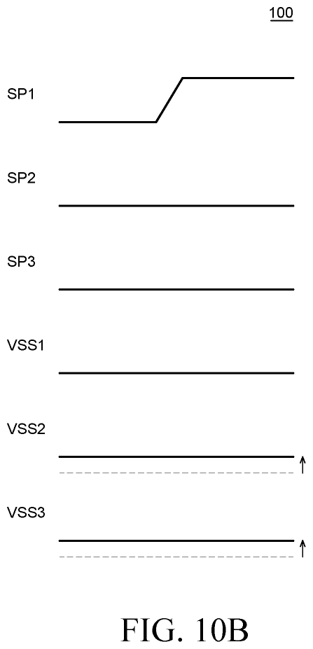

Meanwhile, in the display device 100 according to an example embodiment of the present disclosure, in addition to forming the leakage current blocking unit 120B in the light emitting element 120, a low potential power supply voltage supplied to each sub-pixel SP can be adjusted, so that leakage current can be further reduced. Hereinafter, a method for reducing leakage current using a low potential power supply voltage will be described with reference to FIG. 9A to FIG. 10B.

FIG. 9A is a schematic circuit diagram of sub-pixels of a display device according to a comparative example. FIG. 9B is a diagram for explaining a driving current and a low potential power supply voltage of the sub-pixels of the display device according to the comparative example. FIG. 10A is a schematic circuit diagram of sub-pixels of the display device according to an example embodiment of the present disclosure. FIG. 10B is a diagram for explaining a driving current and low potential power supply voltages of the sub-pixel of the display device according to an example embodiment of the present disclosure. The sub-pixel SP can further include a switching transistor, a storage capacitor and the like, in addition to the driving transistor DT, but only the driving transistor DT is illustrated in FIGS. 9A and 10A for convenience of description. In a display device 10 according to the comparative example, all of a plurality of sub-pixels SP are connected to the same low potential power line VSS. In the display device 100 according to an example embodiment, each of the plurality of sub-pixels SP in the pixel PX is connected to one of a first low potential power line VSS1, a second low potential power line VSS2, or a third low potential power line VSS3. The display device 10 according to the comparative example differs from the display device 100 according to an example embodiment of the present disclosure in that all of the plurality of sub-pixels SP are connected to the same low potential power line VSS, but other configurations of the display device 10 according to the comparative example are substantially identical to those of the display device 100 according to an example embodiment of the present disclosure.

First, referring to FIG. 9A, in the display device 10 according to the comparative example, one light emitting element 120 is disposed in a plurality of sub-pixels SP. A driving transistor DT connected between the light emitting element 120 and the low potential power supply line VSS is individually disposed in each of the plurality of sub-pixels SP, so that the driving transistors DT can independently drive the plurality of light emitting layers 122 included in one light emitting element 120.

Also, the plurality of sub-pixels SP can be connected to the same high potential power supply line VDD and the same low potential power supply line VSS. That is, the same high potential power supply voltage and the same low potential power supply voltage can be supplied to all of the plurality of sub-pixels SP. Specifically, the light emitting element 120 connected between the high potential power supply line VDD and the driving transistor DT can receive a driving current flowing from the high potential power supply line VDD to the low potential power supply line VSS and emit light, and intensity of the driving current can be controlled by the driving transistor DT.

Referring to FIG. 9B, assuming that only the first sub-pixel SP1 emits light and the second sub-pixel SP2 and the third sub-pixel SP3 do not emit light, the driving current can flow in the first sub-pixel SP1. However, it can be confirmed that the driving current flowing through the first sub-pixel SP1 leaks into the second sub-pixel SP2 and the third sub-pixel SP3 that are not supposed to emit light, through the first semiconductor layer 121, so a portion of the driving current flows in the second sub-pixel SP2 and the third sub-pixel SP3. That is, the driving current flowing to the light emitting layer 122 of the first sub-pixel SP1 can leak through the first semiconductor layer 121 and flow to adjacent second and third sub-pixels SP2 and SP3. Accordingly, light can be emitted even from the light emitting layers 122 of the second sub-pixel SP2 and the third sub-pixel SP3, causing color coordinate distortion and degradation in display quality.

Referring to FIG. 10A, in the display device 100 according to an example embodiment of the present disclosure, one light emitting element 120 is disposed in a plurality of sub-pixels SP. A driving transistor DT connected between the light emitting element 120 and the low potential power supply line VSS1, VSS2, and VSS3 is individually disposed in each of the plurality of sub-pixels SP, so that the driving transistors DT can independently drive the plurality of light emitting layers 122 included in one light emitting element 120. The driving transistor DT of each of the plurality of sub-pixels can be electrically connected to the first semiconductor layer 121 through each of the plurality of first electrodes 124.

Also, the plurality of sub-pixels SP are connected to the same high potential power supply line VDD. On the other hand, in the display device 100 according to an example embodiment of the present disclosure unlike the display device 10 according to the comparative example, each of the plurality of sub-pixels SP can be connected to different low potential power supply lines VSS1, VSS2, and VSS3, and the light emitting element 120 can be driven (e.g., the driving transistor DT in each sub-pixel SP is individually connected to its own low potential power supply line, which can be individually tuned and adjusted). That is, the same high potential power supply voltage is supplied to all of the plurality of sub-pixels SP, but low potential power supply voltages of different levels can be supplied to each of the plurality of sub-pixels SP. For example, the driving transistor DT of the first sub-pixel SP1 is connected to a first low potential power supply line VSS1, the driving transistor DT of the second sub-pixel SP2 is connected to a second low potential power supply line VSS2, and the driving transistor DT of the third sub-pixel SP3 is connected to a third low potential power supply line VSS3. Accordingly, as each of the plurality of sub-pixels SP are connected to different low potential power supply lines VSS1, VSS2, and VSS3, low potential power supply voltages of different levels can be supplied to each of the plurality of sub-pixels SP.

Referring to FIG. 10B, assuming that only the first sub-pixel SP1 emits light and the second sub-pixel SP2 and the third sub-pixel SP3 do not emit light, a driving current flowing from the high potential power supply line VDD to the first low potential power supply line VSS1 can be supplied to the light emitting element 120 in the first sub-pixel SP1.

In this situation, a low potential power supply voltage of a relatively high level (a level higher than that of a voltage applied to the first low potential power supply line VSS1) can be supplied to the second low potential power supply line VSS2 and the third low potential power supply line VSS3 connected to the second sub-pixel SP2 and the third sub-pixel SP3 that do not emit light. In this situation, since a voltage difference between the high potential power supply line VDD and the second low potential power supply line VSS2 is reduced, so intensity of current flowing from the high potential power supply line VDD to the second low potential power supply line VSS2 can be reduced. Also, since a voltage difference between the high potential power line VDD and the third low potential power line VSS3 is reduced, intensity of current flowing from the high potential power line VDD to the third low potential power line VSS3 can be reduced. Therefore, even if some of the driving current of the first sub-pixel SP1 leaks through the first semiconductor layer 121 to the adjacent second and third sub-pixels SP2 and SP3, a flow of leakage current can be minimized or prevented by reducing the voltage difference between the high potential power supply line VDD and the low potential power supply line VSS for the corresponding adjacent sub-pixels.

Therefore, in the display device 100 according to an example embodiment of the present disclosure, the plurality of sub-pixels SP are connected to the different first, second, third low potential power supply lines VSS1, VSS2 and VSS3, and low potential power supply voltages of different levels are supplied to the low potential power supply lines VSS1, VSS2 and VSS3 according to whether or not the sub-pixels SP emit light, so that leakage current between the plurality of sub-pixels SP corresponding to one light emitting element 120 can be reduced. For example, a low potential power supply voltage having a level relatively higher than that of an existing low potential power supply voltage is supplied to the sub-pixels SP that do not emit light, so that a flow of leakage current therethrough can be reduced. Accordingly, when the plurality of sub-pixels SP are implemented with only one light emitting element 120, the flow of leakage current to the adjacent sub-pixels SP through the first semiconductor layer 121 can be further minimized, so that color coordinate distortion can be minimized or prevented, and display quality can be improved.

The example embodiments of the present disclosure can also be described as follows:

According to an aspect of the present disclosure, there is provided a display device. The display device includes a substrate on which a plurality of pixels each including a plurality of sub-pixels are defined, a light emitting element disposed in each of the plurality of pixels, and a plurality of color conversion members disposed on the light emitting element in each of the plurality of sub-pixels. One light emitting element is disposed in the plurality of sub-pixels, and the one light emitting element overlaps the plurality of color conversion members.

The light emitting element can include a first semiconductor layer overlapping all of the plurality of sub-pixels, a plurality of light emitting layers disposed on the first semiconductor layer and overlapping each of the plurality of sub-pixels, a plurality of second semiconductor layers disposed on each of the plurality of light emitting layers, a plurality of first electrodes disposed on a side surface and a lower surface of the first semiconductor layer and overlapping each of the plurality of sub-pixels, and a plurality of second electrodes disposed on the plurality of second semiconductor layers and overlapping each of the plurality of sub-pixels.

The light emitting element can further include a groove disposed in the plurality of light emitting layers and the plurality of second semiconductor layers and disposed along a boundary of the plurality of sub-pixels, and the plurality of light emitting layers and the plurality of second semiconductor layers can be separated from each other with the groove therebetween.

The display device can further include a bank disposed along a boundary of the plurality of sub-pixels and disposed to fill the groove.

The plurality of color conversion members can include a plurality of color conversion layers disposed on the bank in each of the plurality of sub-pixels and including a color conversion material absorbing light emitted from the plurality of light emitting layers and emitting light of a different color, and a plurality of color filters disposed on the plurality of color conversion layers.

On a plane, the plurality of color conversion members can have a size larger than that of the light emitting element, so that each of the plurality of color conversion members includes an overlapping portion that overlaps the light emitting element and a non-overlapping portion that does not overlap the light emitting element.

The display device can further include a reflective layer disposed between the bank and the color conversion member and overlapping the light emitting element. The reflective layer can be configured to reflect light emitted from the light emitting element to the non-overlapping portion of each of the plurality of color conversion members.

The display device can further include a driving transistor disposed in each of the plurality of sub-pixels between the substrate and the light emitting element. The driving transistor of each of the plurality of sub-pixels can be electrically connected to the first semiconductor layer through each of the plurality of first electrodes.

The first semiconductor layer can further include a leakage current blocking unit overlapping the groove and integrally formed with the first semiconductor layer. The first semiconductor layer can be formed of crystal having regularity, and the leakage current blocking unit can be a portion from which the regularity of the first semiconductor layer is removed.

The driving transistor can be configured to control a driving current supplied to the light emitting element in each of the plurality of sub-pixels, and the leakage current blocking unit can be configured to block the driving current of each of the plurality of sub-pixels from flowing to the other sub-pixels through the first semiconductor layer.

The display device can further include a high potential power supply line electrically connected to each of the plurality of second electrodes, and a low potential power supply line electrically connected to the driving transistor. The high potential power supply line, the light emitting element, the driving transistor, and the low potential power supply line can be connected in series in each of the plurality of sub-pixels.

The plurality of sub-pixels can include a first sub-pixel, a second sub-pixel, and a third sub-pixel. The low potential power supply line can include a first low potential power supply line electrically connected to the driving transistor of the first sub-pixel, a second low potential power supply line electrically connected to the driving transistor of the second sub-pixel, and a third low potential power supply line electrically connected to the driving transistor of the third sub-pixel.

When only the first sub-pixel among the plurality of sub-pixels emits light, a voltage having a level higher than that of a voltage applied to the first low potential power supply line can be applied to the second low potential power supply line and the third low potential power supply line.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. display device, comprising:
a plurality of pixels disposed on a substrate;
at least two sub-pixels disposed in a same pixel among of the plurality of pixels;
a light emitting element disposed in the same pixel; and
a plurality of color conversion members disposed in the at least two sub-pixels, each of the plurality of color conversion members overlapping with at least a portion of the light emitting element,
wherein the light emitting element is shared by the at least two sub-pixels in the same pixel.

2. The display device of claim 1, wherein the light emitting element includes:
a first semiconductor layer overlapping with at least a portion of each of the at least two-subpixels in the same pixel;
a plurality of light emitting layers disposed on the first semiconductor layer and overlapping with at least a portion of one of the at least two-subpixels in the same pixel;
a plurality of second semiconductor layers respectively disposed on the plurality of light emitting layers in the same pixel;
a plurality of first electrodes disposed in the same pixel, each of the plurality of first electrodes being disposed on a side surface and a lower surface of the first semiconductor layer and overlapping with at least a portion of one of the at least two-subpixels in the same pixel; and
a plurality of second electrodes respectively disposed on the plurality of second semiconductor layers in the same pixel and overlapping with at least a portion of one of the at least two-subpixels in the same pixel.

3. The display device of claim 2, wherein the light emitting element further includes a groove disposed in the plurality of light emitting layers and the plurality of second semiconductor layers, the groove extending along a boundary between the at least two sub-pixels, and
wherein the plurality of light emitting layers and the plurality of second semiconductor layers are separated from each other by the groove.

4. The display device of claim 3, further comprising:
a first bank disposed in the groove and extending along the boundary between the at least two sub-pixels.

5. The display device of claim 4, wherein the plurality of color conversion members include:
a plurality of color conversion layers disposed on the first bank in the plurality of sub-pixels, each of the plurality of color conversion layers including a color conversion material configured to absorb light emitted from one of the plurality of light emitting layers and emit light of a different color than the light emitting from the corresponding one of the plurality of light emitting layers; and
a plurality of color filters disposed on the plurality of color conversion layers.

6. The display device of claim 5, wherein each of the plurality of color conversion members in the same pixel is larger than the light emitting element,
wherein at least a portion of each of the plurality of color conversion members overlaps with at least a portion of the light emitting element, and
wherein each of the plurality of color conversion members includes a non-overlapping portion that does not overlap the light emitting element.

7. The display device of claim 6, further comprising:
a first reflective layer disposed between the first bank and at least one of the plurality of color conversion members,
wherein the first reflective layer is configured to reflect light emitted from the light emitting element toward the non-overlapping portion of at least one of the plurality of color conversion members.

8. The display device of claim 7, wherein the first reflective layer has a shape corresponding to a planar shape of the light emitting element.

9. The display device of claim 4, further comprising:
a second bank disposed along a boundary between at least two pixels among the plurality of pixels.

10. The display device of claim 9, wherein the second bank is connected to a portion of the first bank.

11. The display device of claim 4, further comprising:
a second reflective layer disposed on a side surface of the first bank and configured to reflect light irradiated towards the side surface of the first bank from the light emitting element.

12. The display device of claim 9, further comprising:
a third reflective layer disposed on a side surface of the second bank and configured to reflect light irradiated towards the side surface of the second bank from the light emitting element.

13. The display device of claim 3, further comprising:
a driving transistor disposed in each of the at least two sub-pixels in an area between the substrate and the light emitting element,
wherein the driving transistor sub-pixels is electrically connected to the first semiconductor layer through one of the plurality of first electrodes.

14. The display device of claim 13, wherein the first semiconductor layer further includes a leakage current blocking part overlapping with the groove, the leakage current blocking part being integrally formed with the first semiconductor layer, and
wherein the first semiconductor layer is formed of crystal having regularity, and the leakage current blocking unit is a portion from which the regularity of the first semiconductor layer is removed or damaged.

15. The display device of claim 14, wherein the driving transistor is configured to control a driving current supplied to the light emitting element, and
wherein the leakage current blocking part is configured to block the driving current from flowing between adjacent sub-pixels among the at least two sub-pixels.

16. The display device of claim 13, further comprising:
a high potential power supply line electrically connected to each of the plurality of second electrodes; and
a low potential power supply line electrically connected to the driving transistor,
wherein the high potential power supply line, the light emitting element, the driving transistor, and the low potential power supply line are connected in series in each of the at least two sub-pixels.

17. The display device of claim 16, wherein the at least two sub-pixels include a first sub-pixel, a second sub-pixel, and a third sub-pixel,
wherein the low potential power supply line includes:
a first low potential power supply line electrically connected to the driving transistor of the first sub-pixel;
a second low potential power supply line electrically connected to the driving transistor of the second sub-pixel; and
a third low potential power supply line electrically connected to the driving transistor of the third sub-pixel.

18. The display device of claim 17, wherein when only the first sub-pixel among the first, second and third sub-pixels emits light, a voltage having a level higher than that of a voltage applied to the first low potential power supply line is applied to the second low potential power supply line and the third low potential power supply line.

19. The display device of claim 2, wherein the light emitting element further includes a groove disposed in a central portion of the light emitting element, and
wherein the plurality of light emitting layers for the at least two sub-pixels are separated from each other by the groove.

20. The display device of claim 1, wherein a same high potential power supply voltage is supplied to all of the plurality of sub-pixels, and
wherein low potential power supply voltages of different levels are supplied to each of the at least two sub-pixels in the same pixel.

21. A display device, comprising:
a first sub-pixel configured to emit a first color light;
a second sub-pixel configured to emit a second color light different than the first color light; and
one light emitting diode overlapping with at least a portion of the first sub-pixel and at least a portion of the second sub-pixel.
